(19) United States
(12) Patent Application Publication
(10) Pub. No.: US 2025/0358539 A1
(43) Pub. Date: Nov. 20, 2025

(54) IMAGING APPARATUS, CONTROL METHOD, CONTROL PROGRAM, AND IMAGING ELEMENT

(71) Applicant: FUJIFILM Corporation, Tokyo (JP)

(72) Inventors: Yoshinori FURUTA, Saitama-shi (JP); Kazuya ODA, Saitama-shi (JP); Tomoyuki KAWAI, Saitama-shi (JP); Yota AKASHI, Saitama-shi (JP); Makoto KOBAYASHI, Saitama-shi (JP); Seiji TANAKA, Saitama-shi (JP)

(73) Assignee: FUJIFILM Corporation, Tokyo (JP)

(21) Appl. No.: 19/280,134

(22) Filed: Jul. 25, 2025

Related U.S. Application Data
(63) Continuation of application No. PCT/JP2023/045790, filed on Dec. 20, 2023.

(30) Foreign Application Priority Data
Jan. 31, 2023 (JP) 2023-013457

(51) Int. Cl. H04N 25/585; H04N 25/77

(52) U.S. Cl. CPC H04N 25/585; H04N 25/77

(57) ABSTRACT

An imaging apparatus includes: an imaging element that includes plural pixels; and a processor, the plural pixels include first pixels in each of which a light reducing member having plural openings is disposed and second pixels in each of which the light reducing member is not provided, the processor is configured to: perform addition control of adding signals generated by two or more of the plural pixels together, and in the addition control, control of adding first signals generated by the first pixels together and adding second signals generated by the second pixels together is performed.

### CROSS REFERENCE TO RELATED APPLICATION

This is a continuation of International Application No. PCT/JP2023/045790 filed on Dec. 20, 2023, and claims priority from Japanese Patent Application No. 2023-013457 filed on Jan. 31, 2023, the entire disclosures of which are incorporated herein by reference.

### BACKGROUND OF THE INVENTION

### 1. Field of the Invention

The present invention relates to an imaging apparatus, a control method, a computer readable medium storing a control program, and an imaging element.

### 2. Description of the Related Art

JP2022-099612A discloses a solid-state imaging element comprising a wafer substrate having a plurality of photoelectric conversion elements, an organic film formed on the wafer substrate with a resin having a carboxylic acid in a skeleton as a main component, a light shielding layer formed on the organic film with a titanium-based black material as a main component and having a plurality of openings, and a plurality of microlenses disposed on the openings or in the openings.

JP2012-019360A discloses a solid-state imaging device comprising a plurality of pixels each having a photoelectric conversion element, and a light shielding layer covering the photoelectric conversion element, in which the light shielding layer has, in the photoelectric conversion element of each of the plurality of pixels, a light shielding unit for blocking a part of incident light on the photoelectric conversion element and an opening portion for allowing transmission of a remaining part of the incident light, the plurality of pixels include at least two types of pixels having different areas of the photoelectric conversion elements in a plan view, and the larger the area of the pixel in the plan view of the photoelectric conversion element, the larger the area of the light shielding unit.

JP2009-146957A discloses a solid-state imaging device comprising a semiconductor substrate in which a photoelectric conversion element is formed on a main surface, and which comprises a light-receiving pixel region, a boundary pixel region, and a light shielding pixel region, an interlayer insulating film formed on the semiconductor substrate, a wiring layer formed on the interlayer insulating film, a first in-layer lens formed on the interlayer insulating film in the light-receiving pixel region, a first incident light restriction film formed on the interlayer insulating film in the boundary pixel region, and a light shielding film formed on the interlayer insulating film in the light shielding pixel region, in which the boundary pixel region is formed between the light-receiving pixel region and the light shielding pixel region.

JP2016-052041A discloses a solid-state imaging element comprising a pixel unit in which one of microlenses is formed for a plurality of pixels such that a boundary of the microlens coincides with a boundary of the pixel, and a correction circuit that corrects a sensitivity difference between the pixels in the pixel unit based on a correction coefficient.

JP1993-86670B (JP-H5-86670B) discloses that a light shielding film having a large number of openings in a mesh shape is used as restricting means for partially restricting incident light for each pixel of an imaging element.

JP2022-102594A discloses an imaging element having an imaging pixel and a focus detection pixel.

### SUMMARY OF THE INVENTION

An imaging apparatus, a control method, a computer readable medium storing a control program, and an imaging element according to one embodiment of the technology of the present disclosure are as follows.

(1)

An imaging apparatus comprising:
an imaging element that includes a plurality of pixels; and
a processor,
in which the plurality of pixels include first pixels in each of which a light reducing member having a plurality of openings is disposed and second pixels in each of which the light reducing member is not provided,
the processor is configured to:
   perform addition control of adding signals generated by two or more of the plurality of pixels together, and
in the addition control, control of adding first signals generated by the first pixels together and adding second signals generated by the second pixels together is performed.
   (2)

The imaging apparatus according to (1),
in which the first pixels includes a plurality of types in which dispositions of the plurality of openings are different from each other, and
two or more first signals added together in the addition control include signals generated by the first pixels of different types.
   (3)

The imaging apparatus according to (2),
in which the plurality of types of first pixels have different phases of the plurality of openings.
   (4)

The imaging apparatus according to (2) or (3),
in which the imaging element has a pixel group including a plurality of the first pixels which are two-dimensionally arranged, and
in the pixel group, one of the first pixels is set as a pixel of interest, and a first pixel of a type different from the pixel of interest is disposed in a first pixel closest to the pixel of interest in a first direction of the pixel of interest and in a first pixel closest to the pixel of interest in a second direction intersecting the first direction of the pixel of interest.
   (5)

The imaging apparatus according to (4),
in which the processor is configured to:
   perform first addition control of adding a first signal generated by the pixel of interest and a first signal generated by the first pixel closest to the pixel of interest in the first direction of the pixel of interest together, and second addition control of adding the first signal generated by the pixel of interest and a first signal generated by the first pixel closest to the pixel of interest in the second direction of the pixel of interest together.
      (6)

The imaging apparatus according to (2) or (3),
in which the imaging element has a pixel group including a plurality of the first pixels arranged in one direction, and
in the pixel group, one of the first pixels is set as a pixel of interest, and one of the first pixels on both sides closest to the pixel of interest is the first pixel of the same type as the pixel of interest and the other is the first pixel of a different type from the pixel of interest.
   (7)

The imaging apparatus according to (6),
in which the processor is configured to:
   perform, on one side of the pixel of interest in the one direction, third addition control of adding a first signal generated by the pixel of interest and a first signal generated by a first pixel second closest to the pixel of interest together, and fourth addition control of adding the first signal generated by the pixel of interest and a first signal generated by a first pixel closest to the pixel of interest together.
      (8)

The imaging apparatus according to any one of (1) to (3),
in which the processor is configured to:
   add digitally converted signals together in the addition control.
      (9)

An imaging apparatus comprising:
an imaging element that includes a plurality of pixels; and
a processor,
in which the plurality of pixels include a first pixel in which a light reducing member having a plurality of openings is disposed and a second pixel in which the light reducing member is not provided,
the processor is configured to:
   perform addition control of adding signals generated by two or more of the plurality of pixels together, and
in the addition control, control of adding a first signal generated by the first pixel and a second signal generated by the second pixel together is performed.
   (10)

The imaging apparatus according to (9),
in which the processor is configured to:
   perform control of adding a digitally converted first signal and a digitally converted second signal together.
      (11)

A control method of controlling an imaging element that includes a plurality of pixels,
in which the plurality of pixels include first pixels in each of which a light reducing member having a plurality of openings is disposed and second pixels in each of which the light reducing member is not provided,
the method comprising:
performing addition control of adding signals generated by two or more of the plurality of pixels together, and
in the addition control, control of adding first signals generated by the first pixels together and adding second signals generated by the second pixels together is performed.
   (12)

A computer readable medium storing a control program of controlling an imaging element that includes a plurality of pixels,
in which the plurality of pixels include first pixels in each of which a light reducing member having a plurality of openings is disposed and second pixels in each of which the light reducing member is not provided,
the program causing a processor to execute a step of:
performing addition control of adding signals generated by two or more of the plurality of pixels together, and
in the addition control, control of adding first signals generated by the first pixels together and adding second signals generated by the second pixels together is performed.
   (13)

An imaging element comprising:
a plurality of pixels,
in which the plurality of pixels include first pixels in each of which a light reducing member having a plurality of openings is disposed and second pixels in each of which the light reducing member is not provided, and
in a case where an instruction to add signals generated by two or more of the plurality of pixels together and to output the added signals is received, the imaging element adds first signals generated by the first pixels together, adds second signals generated by the second pixels together, and outputs the added signals.

### BRIEF DESCRIPTION OF THE DRAWINGS

FIG. 1 is a diagram showing a schematic configuration of a digital camera 100 which is an embodiment of an imaging apparatus according to the present invention.

FIG. 2 is a schematic plan view showing a schematic configuration of an imaging element 5 shown in FIG. 1.

FIG. 3 is a schematic diagram showing a partially enlarged imaging surface 60 of the imaging element 5 shown in FIG. 2.

FIG. 4 is a diagram showing sensitivity characteristics of a high-sensitivity pixel 61GH and a low-sensitivity pixel 61GL.

FIG. 5 is a schematic cross-sectional view of a pixel 61R and the high-sensitivity pixel 61GH in a range A1 shown in FIG. 3.

FIG. 6 is a schematic cross-sectional view of a pixel 61B and the low-sensitivity pixel 61GL in a range A2 shown in FIG. 3.

FIG. 7 is a schematic plan view of a light reducing member 70a and a light reducing member 70b shown in FIG. 6 as viewed from a microlens ML side.

FIG. 8 is a diagram showing a modification example of the light reducing member 70b.

FIG. 9 is a diagram showing a modification example of the light reducing member 70b.

FIG. 10 is a schematic diagram for describing a change in a sensitivity difference between the high-sensitivity pixel 61GH and the low-sensitivity pixel 61GL depending on an image height.

FIG. 11 is a graph showing output changes of the low-sensitivity pixel 61GL and the high-sensitivity pixel 61GH depending on the image height.

FIG. 12 is a schematic diagram showing a combination of pixels to be added together in second imaging control.

FIG. 13 is a schematic diagram showing another example of a combination of pixels to be added together in the second imaging control.

FIG. 14 is a diagram showing a modification example of pixel disposition of the imaging element 5.

FIG. 15 is a diagram for describing another driving example of the imaging element 5 shown in FIG. 14.

FIG. 16 is a diagram showing another modification example of the pixel disposition of the imaging element 5.

FIG. 17 is a diagram showing an exterior of a smartphone 200.

FIG. 18 is a block diagram showing a configuration of the smartphone 200 shown in FIG. 17.

### DESCRIPTION OF THE PREFERRED EMBODIMENTS

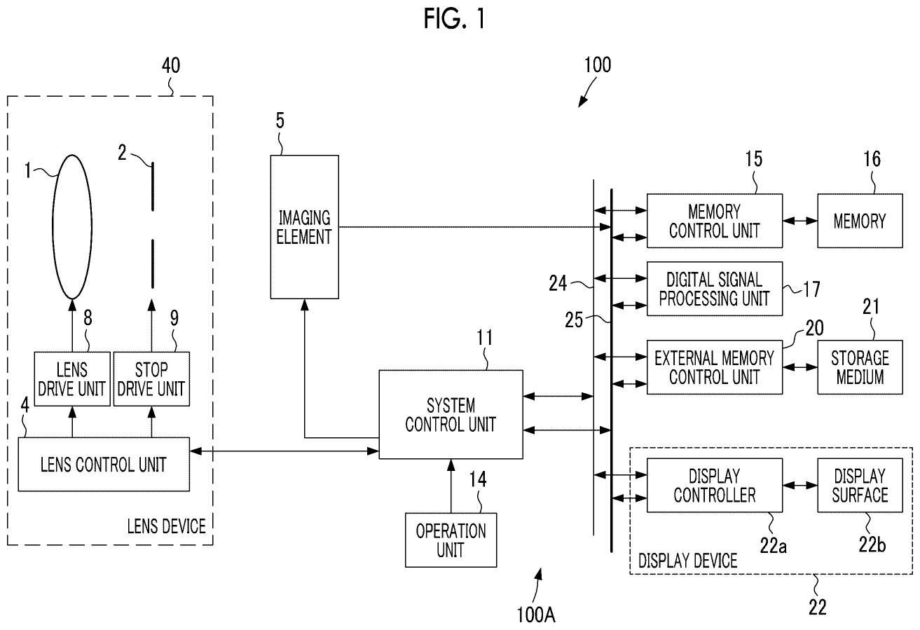

FIG. 1 is a diagram showing a schematic configuration of a digital camera 100 which is an embodiment of an imaging apparatus according to the present invention. The digital camera 100 shown in FIG. 1 comprises a lens device 40 including an imaging lens 1, a stop 2, a lens drive unit 8 that drives the imaging lens 1, a stop drive unit 9 that drives the stop 2, and a lens control unit 4 that controls the lens drive unit 8 and the stop drive unit 9, and a body part 100A.

The body part 100A comprises an imaging element 5, a system control unit 11 that manages and controls the entire electric control system of the digital camera 100, an operation unit 14, a display device 22, a memory 16 including a random access memory (RAM), a read only memory (ROM), and the like, and a memory control unit 15 that controls data storage in the memory 16 and data readout from the memory 16, a digital signal processing unit 17, and an external memory control unit 20 that controls data storage in a storage medium 21 and data readout from the storage medium 21.

The lens device 40 may be attachable to and detachable from the body part 100A or may be integrated with the body part 100A. The imaging lens 1 includes at least one of a focus lens or a zoom lens that is movable in an optical axis direction.

The focus lens is a lens for adjusting a focal point of an imaging optical system including the imaging lens 1 and the stop 2, and is composed of a single lens or of a plurality of lenses. By moving the focus lens in the optical axis direction, a position of a principal point of the focus lens (hereinafter, also referred to as a focus lens position) changes along the optical axis direction, and a focal position on a subject side is changed. A liquid lens of which a position of a principal point in the optical axis direction can be changed by electric control may be used as the focus lens.

The zoom lens is a lens for changing a focal length of the imaging optical system including the imaging lens 1 and the stop 2, and is composed of a single lens or of a plurality of lenses. By moving the zoom lens in the optical axis direction, the zoom magnification is changed.

The lens control unit 4 of the lens device 40 changes the focus lens position or the zoom lens position by controlling the lens drive unit 8 based on a lens drive signal transmitted from the system control unit 11. The lens control unit 4 of the lens device 40 changes an amount of opening (F value) of the stop 2 by controlling the stop drive unit 9 based on a driving control signal transmitted from the system control unit 11.

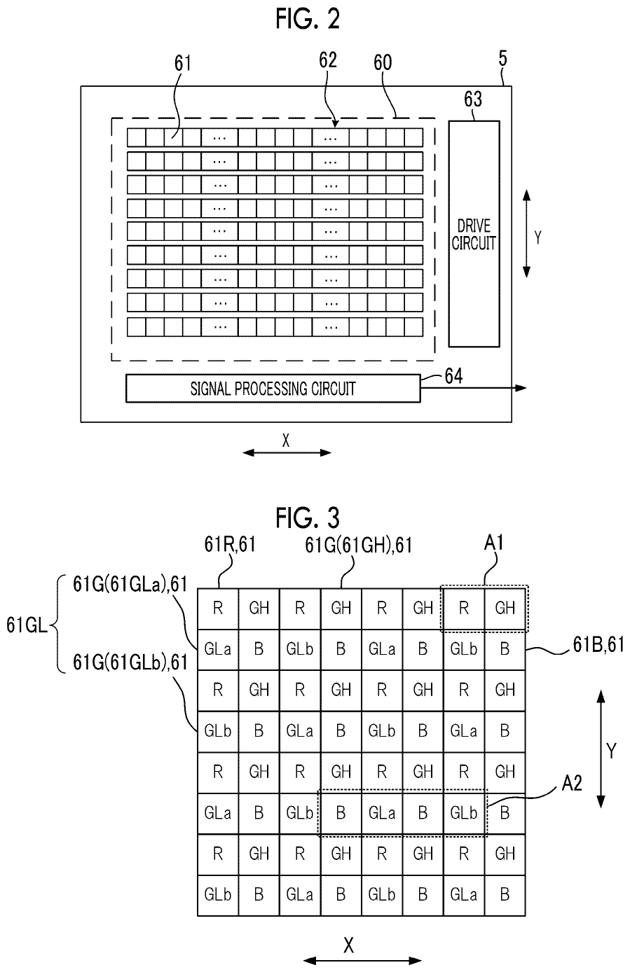

The imaging element 5 images a subject through the imaging optical system including the imaging lens 1 and the stop 2. The imaging element 5 includes an imaging surface 60 (refer to FIG. 2) on which a plurality of pixels are two-dimensionally arranged, converts a subject image formed on the imaging surface 60 by the imaging optical system into image signals by the plurality of pixels, and outputs the image signals.

For example, a complementary metal-oxide semiconductor (CMOS) image sensor or a charge coupled device (CCD) image sensor is used as the imaging element 5. Hereinafter, an example in which the imaging element 5 is a CMOS image sensor will be described.

The system control unit 11 manages and controls the entire digital camera 100 and has a hardware structure corresponding to various processors that perform processing by executing programs. The programs (including a control program) executed by the system control unit 11 are stored in the ROM (non-transitory storage medium) of the memory 16.

Examples of the various processors include a central processing unit (CPU) that is a general-purpose processor performing various types of processing by executing a program, a programmable logic device (PLD) such as a field programmable gate array (FPGA) that is a processor of which a circuit configuration can be changed after manufacture, or a dedicated electric circuit such as an application specific integrated circuit (ASIC) that is a processor having a circuit configuration dedicatedly designed to execute specific processing. More specifically, a structure of these various processors is an electric circuit in which circuit elements such as semiconductor elements are combined.

The system control unit 11 may be configured with one of the various processors or may be configured with a combination of two or more processors of the same type or of different types (for example, a combination of a plurality of FPGAs or a combination of a CPU and an FPGA).

The system control unit 11 drives the imaging element 5 and the lens device 40 and outputs the subject image captured through the imaging optical system of the lens device 40 as the image signal. By processing the image signal output from the imaging element 5 via the digital signal processing unit 17, captured image data that is data suitable for display on the display device 22 or is data suitable for storage in the storage medium 21 is generated.

An instruction signal from a user is input to the system control unit 11 through the operation unit 14. The operation unit 14 includes a touch panel integrated with a display surface 22b, and various buttons and the like.

The display device 22 comprises the display surface 22b configured with an organic electroluminescence (EL) panel, a liquid crystal panel, or the like, and a display controller 22a that controls display on the display surface 22b.

The memory control unit 15, the digital signal processing unit 17, the external memory control unit 20, and the display controller 22a are connected to each other through a control bus 24 and through a data bus 25 and are controlled in accordance with instructions from the system control unit 11.

FIG. 2 is a schematic plan view showing a schematic configuration of the imaging element 5 shown in FIG. 1. The imaging element 5 comprises an imaging surface 60 on which a plurality of pixel rows 62 consisting of a plurality of pixels 61 arranged in a row direction X are arranged in a column direction Y intersecting (in the example in the drawing, orthogonal to) the row direction X, a drive circuit 63 that drives the pixels 61 arranged on the imaging surface 60, and a signal processing circuit 64 that processes pixel signals read out to signal lines from the respective pixels 61 of the pixel rows 62 arranged on the imaging surface 60. The row direction X constitutes one of the first direction and the second direction, and the column direction Y constitutes the other of the first direction and the second direction.

The pixel signal read out from the pixel 61 to the signal line is an analog signal. The signal processing circuit 64 includes a converter that converts an analog signal into a digital signal. The pixel signal read out from the pixel 61 is subjected to digital conversion by the signal processing circuit 64 and is output to the outside of the imaging element 5 as a digital signal. A substrate on which the imaging element 5 is mounted may be provided with a processing circuit that processes a digital pixel signal output from the imaging element 5. A configuration may be adopted in which a substrate on which the system control unit 11 is provided and a substrate on which the imaging element 5 is provided are separately provided, and in which these two substrates are connected to each other.

An angle formed by a ray incident on the pixel 61 and an optical axis of the imaging optical system is defined as a light incidence angle. The light incidence angle is larger at a right end portion and a left end portion of the imaging surface 60 and at an upper end portion and a lower end portion of the imaging surface 60 than at a central portion of the imaging surface 60 (in the vicinity of a place intersecting the optical axis of the imaging optical system). In other words, in a case where a position of the pixel 61 at the intersection with the optical axis on the imaging surface 60 is set as a reference position, the light incidence angle of the pixel 61 increases as the position of the pixel 61 is farther from the reference position.

FIG. 3 is a schematic diagram showing a partially enlarged imaging surface 60 of the imaging element 5 shown in FIG. 2. The plurality of pixels 61 disposed on the imaging surface 60 include pixels each corresponding to a plurality (three in the present embodiment) of wavelength ranges. Specifically, the imaging surface 60 is provided with a pixel 61R (blocks with a character “R” in the drawing) corresponding to a wavelength range of red light, a pixel 61G (blocks with characters “GLa”, “GLb”, and “GH” in the drawing) corresponding to a wavelength range of green light, and a pixel 61B (blocks with a character “B” in the drawing) corresponding to a wavelength range of blue light.

On the imaging surface 60, a pixel row in which the pixel 61R and the pixel 61G are alternately arranged in the row direction X and a pixel row in which the pixel 61G and the pixel 61B are alternately arranged in the row direction X are alternately arranged in the column direction Y. Each pixel 61 provided on the imaging surface 60 receives light in the corresponding wavelength range and outputs a pixel signal corresponding to the amount of the light.

The pixel 61G is provided with two types of pixels, which are a high-sensitivity pixel 61GH (blocks with the character “GH” in the drawing) and a low-sensitivity pixel 61GL (blocks with the characters “GLa” and “GLb” in the drawing). In addition, there are two types of the low-sensitivity pixels 61GL, which are a low-sensitivity pixel 61GLa (blocks with the character “GLa” in the drawing) and a low-sensitivity pixel 61GLb (blocks with the character “GLb” in the drawing). In the example of FIG. 3, the low-sensitivity pixel 61GLa and the low-sensitivity pixel 61GLb are provided in each pixel row 62 including the pixel 61B and the pixel 61G.

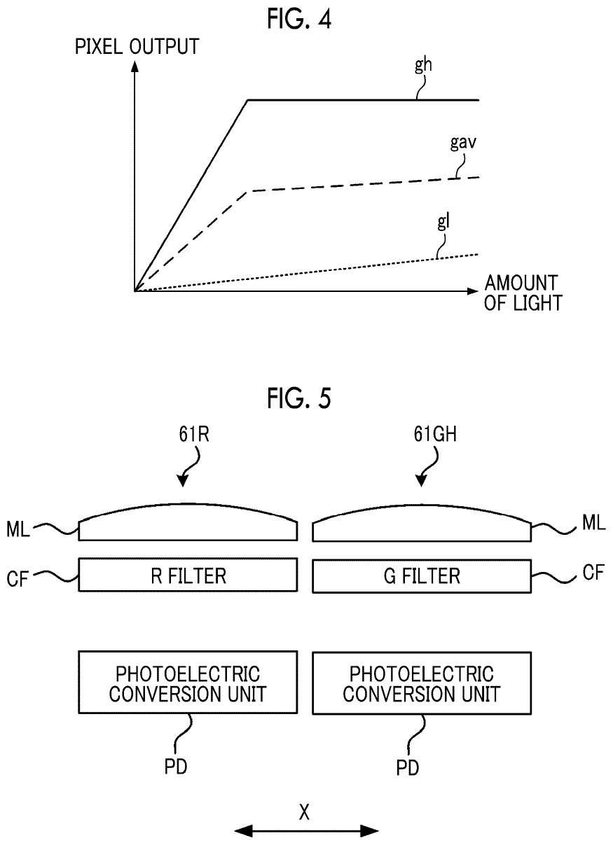

The low-sensitivity pixel 61GL has lower sensitivity than the high-sensitivity pixel 61GH. FIG. 4 is a diagram showing sensitivity characteristics of the high-sensitivity pixel 61GH and the low-sensitivity pixel 61GL. In FIG. 4, a graph gh shows a sensitivity characteristic of the high-sensitivity pixel 61GH, a graph gl shows a sensitivity characteristic of the low-sensitivity pixel 61GL, and a graph gav shows an arithmetic mean of the graph gh and the graph gl. As shown in FIG. 4, even in a case where the same amount of light is incident on the photoelectric conversion units of the low-sensitivity pixel 61GL and the high-sensitivity pixel 61GH, the level of the pixel signal read out from the low-sensitivity pixel 61GL is lower than the level of the pixel signal read out from the high-sensitivity pixel 61GH.

As described above, in the imaging element 5, for the pixel 61G corresponding to the wavelength range of the green light, which is a wavelength range that contributes most to obtaining a brightness signal, two types of the pixel, which are the high-sensitivity pixel 61GH and the low-sensitivity pixel 61GL, are provided. According to this configuration, for example, by calculating an arithmetic mean of the pixel signals of the high-sensitivity pixel 61GH and the low-sensitivity pixel 61GL located in the vicinity of each other, even in a case of imaging a subject region having a high brightness, it is possible to prevent the pixel output from being saturated by widening the dynamic range as in the graph gav of FIG. 4.

The low-sensitivity pixel 61GL constitutes a first pixel. Each pixel 61 (the pixel 61R, the pixel 61GH, and the pixel 61B) except for the low-sensitivity pixel 61GL among the pixels 61 on the imaging surface 60 constitutes a second pixel.

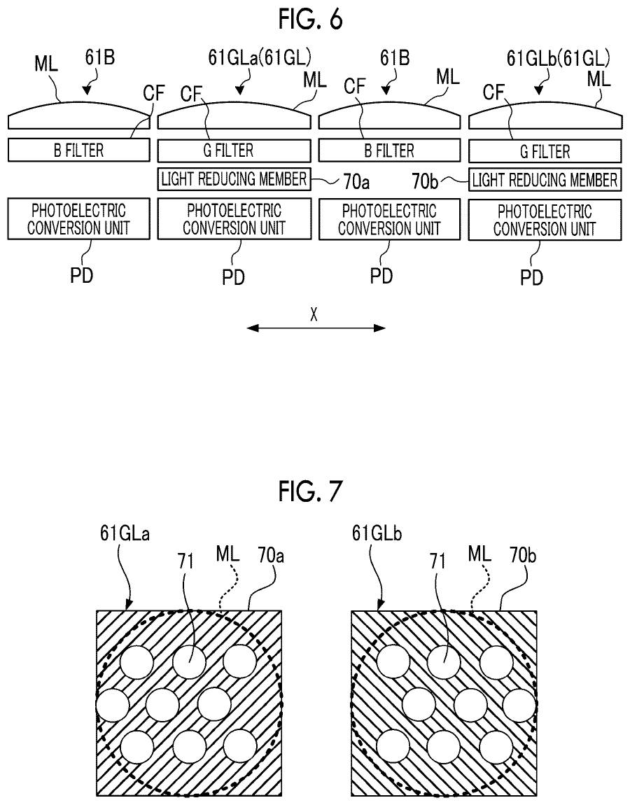

FIG. 5 is a schematic cross-sectional view of the pixel 61R and the high-sensitivity pixel 61GH in a range A1 shown in FIG. 3. FIG. 6 is a schematic cross-sectional view of the pixel 61B and the low-sensitivity pixel 61GL in a range A2 shown in FIG. 3.

As shown in FIGS. 5 and 6, the pixels 61 provided on the imaging surface 60 include, as common constituent to all the pixels 61, a photoelectric conversion unit PD composed of a photodiode or the like, a microlens ML that condenses light from a subject to the photoelectric conversion unit PD, and a color filter CF that is provided between the photoelectric conversion unit PD and the microlens ML and transmits light in a specific wavelength range. Although not shown, a light shielding film that defines a light-receiving area of the photoelectric conversion unit PD, a light shielding film that shields a signal readout circuit disposed close to the photoelectric conversion unit PD, and the like are provided between the photoelectric conversion unit PD and the color filter CF.

The color filter CF (referred to as an R filter in the drawing) included in the pixel 61R transmits the red light, the color filter CF (referred to as a G filter in the drawing) included in the pixel 61G transmits the green light, and the color filter CF (referred to as a B filter in the drawing) included in the pixel 61B transmits the blue light. In a case where red, green, and blue are spectrally divided by the structure of the photoelectric conversion unit PD itself, the color filter CF can be omitted.

The difference between the low-sensitivity pixel 61GL and the other pixels 61 is the presence or absence of a light reducing member 70a or a light reducing member 70b. As shown in FIG. 6, the low-sensitivity pixel 61GL includes the light reducing member 70a or the light reducing member 70b disposed between the color filter CF and the photoelectric conversion unit PD. However, the pixel 61R, the high-sensitivity pixel 61GH, and the pixel 61B do not include the light reducing member 70a and the light reducing member 70b, respectively. It is preferable that the light reducing member 70a and the light reducing member 70b are disposed on a microlens ML side with respect to the light shielding film, respectively.

FIG. 7 is a schematic plan view of the light reducing member 70a and the light reducing member 70b shown in FIG. 6 as viewed from the microlens ML side. Each of the light reducing member 70a and the light reducing member 70b has a plate shape and has a plurality of (nine in the example in the drawing) openings 71 penetrating in a thickness direction thereof. The plurality of openings 71 are arranged in a direction intersecting (specifically, orthogonal to) the optical axis of the imaging optical system. A portion other than the opening 71 in each of the light reducing member 70a and the light reducing member 70b has a light shielding performance, and only light that has passed through the opening 71 and is incident on the microlens ML of the low-sensitivity pixel 61GL reaches the photoelectric conversion unit PD and is converted into a charge.

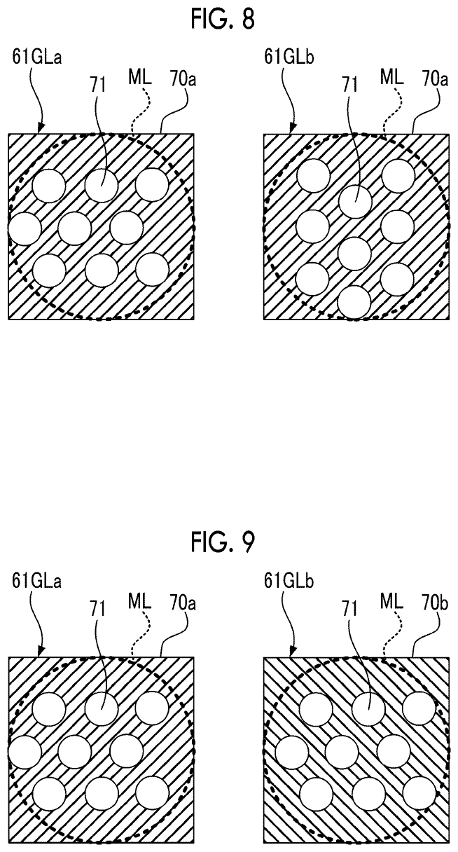

A disposition pattern (hereinafter, also referred to as a first pattern) of the plurality of openings 71 in the light reducing member 70a of the low-sensitivity pixel 61GLa and a disposition pattern (hereinafter, also referred to as a second pattern) of the plurality of openings 71 in the light reducing member 70b of the low-sensitivity pixel 61GLb are different from each other. More specifically, the first pattern and the second pattern have different phases. The fact that the phases of the two patterns are different means that the opening sizes and the positional relationship of the plurality of openings 71 are the same in the two patterns, but the centroid positions of the two patterns are misaligned, the angles of the two patterns are misaligned, and the like. Examples in which the angles of the two patterns are misaligned include a configuration in which the one pattern overlaps the other pattern in a case where the one pattern is rotated by 180 degrees as shown in FIG. 7, and a configuration in which the one pattern overlaps the other pattern in a case where the one pattern is rotated by 90 degrees as shown in FIG. 8. An example in which the centroid positions of the two patterns are misaligned includes a configuration in which the positions of the two patterns in the range overlapping the microlens ML are misaligned in at least one of the row direction X or the column direction Y as shown in FIG. 9.

As described above, the low-sensitivity pixel 61GL is configured to have lower sensitivity than the high-sensitivity pixel 61GH by restricting the amount of light incident on the photoelectric conversion unit PD by the light reducing member 70a or the light reducing member 70b.

It is required that a sensitivity difference between the high-sensitivity pixel 61GH and the low-sensitivity pixel 61GL (an absolute value of a difference in sensitivity between the two pixels or a sensitivity ratio between the two pixels) is substantially constant regardless of a pixel position on the imaging surface 60. However, in the low-sensitivity pixel 61GL including the light reducing member 70a or the light reducing member 70b shown in FIG. 7, the sensitivity difference from the high-sensitivity pixel 61GH may change depending on the position in the imaging surface 60. Hereinafter, a case where the sensitivity difference between the high-sensitivity pixel 61GH and the low-sensitivity pixel 61GL is changed depending on the position in the imaging surface 60 will be described with reference to the drawings.

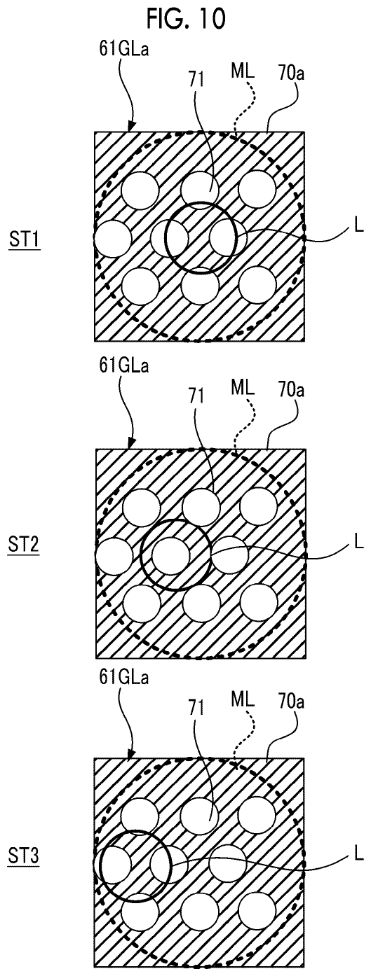

FIG. 10 is a schematic diagram for describing a change in the sensitivity difference between the high-sensitivity pixel 61GH and the low-sensitivity pixel 61GL depending on an image height. FIG. 10 shows a state in which the ray Lis incident on the low-sensitivity pixel 61GLa at a position where the image height is close to 0. A state ST2 shown in FIG. 10 shows a state in which the ray Lis incident on the low-sensitivity pixel 61GLa at a position where the image height is Z1 (a value larger than 0). A state ST3 shown in FIG. 10 shows a state in which the ray L is incident on the low-sensitivity pixel 61GLa at a position where the image height is Z2 (a value larger than Z1). The F value, the focus lens position, and the zoom lens position in each of the state ST1, the state ST2, and the state ST3 are the same.

As can be seen from the comparison between the state ST1 and the state ST2, in the low-sensitivity pixel 61GLa at the position where the image height is 0, a larger amount of the ray L passes through the opening 71 and is incident on the photoelectric conversion unit PD than in the low-sensitivity pixel 61GLa at the position where the image height is Z1. On the other hand, since the high-sensitivity pixel 61GH at the position where the image height is 0 and the high-sensitivity pixel 61GH at the position where the image height is Z1 are not provided with the light reducing member, all of the ray L is incident on the photoelectric conversion unit PD. Therefore, in the state ST1 and the state ST2, the sensitivity difference between the low-sensitivity pixel 61GLa and the high-sensitivity pixel 61GH is larger in the state ST2.

As can be seen from the comparison between the state ST2 and the state ST3, in the low-sensitivity pixel 61GLa at the position where the image height is Z2, a larger amount of the ray L passes through the opening 71 and is incident on the photoelectric conversion unit PD than in the low-sensitivity pixel 61GLa at the position where the image height is Z1. On the other hand, since the high-sensitivity pixel 61GH at the position where the image height is Z2 is not provided with the light reducing member, all of the ray L is incident on the photoelectric conversion unit PD. Therefore, in the state ST2 and the state ST3, the sensitivity difference between the low-sensitivity pixel 61GLa and the high-sensitivity pixel 61GH is smaller in the state ST3.

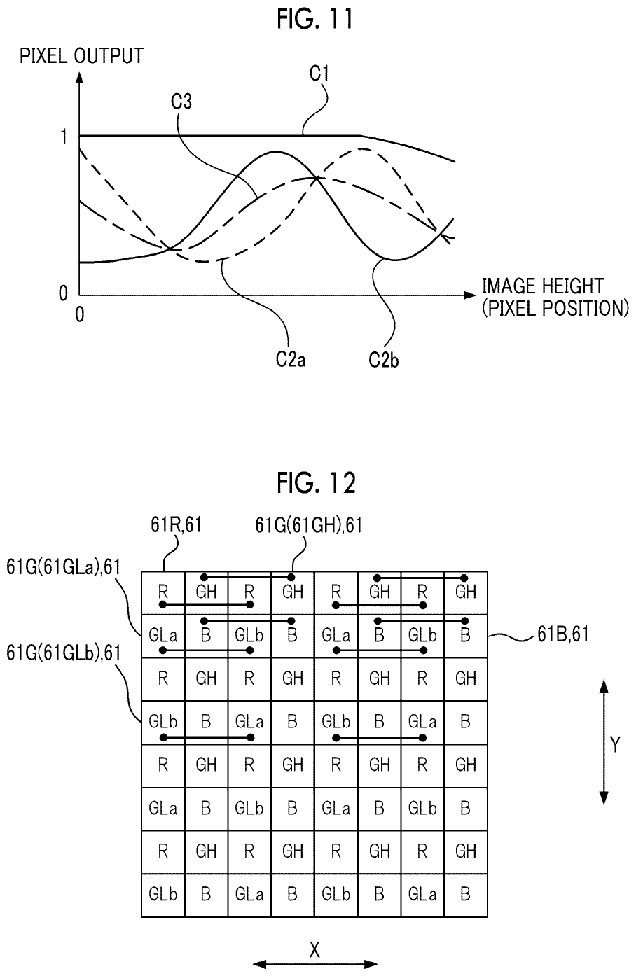

FIG. 11 is a graph showing output changes of the low-sensitivity pixel 61GL and the high-sensitivity pixel 61GH depending on the image height. In FIG. 11, a curve C1 indicates an output of the high-sensitivity pixel 61GH, a curve C2a indicates an output of the low-sensitivity pixel 61GLa, and a curve C2b indicates an output of the low-sensitivity pixel 61GLb.

As in the curve C2a and the curve C2b, in the low-sensitivity pixel 61GL, the peak value of the output is smaller than the peak value of the output of the high-sensitivity pixel 61GH, and the output increases or decreases depending on the image height. The low-sensitivity pixel 61GLa and the low-sensitivity pixel 61GLb have different phases of the plurality of openings 71. Therefore, the shapes of the curve C2a and the curve C2b do not match each other, and there is a relationship in which the peak and the bottom are shifted to left and right. On the other hand, in the high-sensitivity pixel 61GH, there is almost no output fluctuation depending on the image height, and the output gradually decreases toward the peripheral edge of the imaging surface 60 in the peripheral portion of the imaging surface 60 where the image height is large.

In order to make the sensitivity difference between the high-sensitivity pixel 61GH and the low-sensitivity pixel 61GL constant (in other words, in order to reduce output variation of the low-sensitivity pixel 61GL) at any position on the imaging surface 60, it is preferable to correct the output of the low-sensitivity pixel 61GL by multiplying a pixel signal read out from the low-sensitivity pixel 61GL by a gain. It is preferable that the smaller the value of the gain used for the correction, the more the increase in noise can be prevented.

In the present embodiment, the system control unit 11 performs addition control of adding the signals generated by the low-sensitivity pixel 61GLa and the low-sensitivity pixel 61GLb disposed in the vicinity of each other together. The addition control is preferably control for obtaining a signal value obtained by calculating an arithmetic mean of two signals. FIG. 11 shows a curve C3 obtained by calculating an arithmetic mean of the curve C2a and the curve C2b. By obtaining the signal indicated by the curve C3, it is possible to reduce the sensitivity difference between the low-sensitivity pixel 61GL and the high-sensitivity pixel 61GH caused by the structure of the light reducing member 70a or the light reducing member 70b, and to suppress the noise by reducing the gain for correction.

It is preferable that the low-sensitivity pixel 61GLa and the low-sensitivity pixel 61GLb are disposed to be suitable for the addition control. As shown in FIG. 3, the imaging element 5 is provided with a low-sensitivity pixel group in which the low-sensitivity pixel 61GLa and the low-sensitivity pixel 61GLb are two-dimensionally arranged in the row direction X and the column direction Y. In the low-sensitivity pixel group, in a case where one of the low-sensitivity pixels 61GL is set as a pixel of interest, two types of low-sensitivity pixels 61GL are disposed such that the low-sensitivity pixel 61GL closest to the pixel of interest in the row direction X and the low-sensitivity pixel 61GL closest to the pixel of interest in the column direction Y are different types from the pixel of interest, respectively. According to such a disposition, it is possible to perform control of adding signals generated by two types of low-sensitivity pixels 61GL located closest to each other in the row direction X together and control of adding signals generated by two types of low-sensitivity pixels 61GL located closest to each other in the column direction Y together, and it is possible to implement addition control according to the use application.

Next, an operation example in a case where the system control unit 11 acquires the image signal from the imaging element 5 will be described. The system control unit 11 performs first imaging control of individually acquiring pixel signals from each pixel 61 of the imaging surface 60 and second imaging control of adding pixel signals generated by two or more pixels 61 among the pixels 61 of the imaging surface 60 together and acquiring the added signals.

In the first imaging control, the system control unit 11 controls the imaging element 5 to read out the pixel signal from each pixel 61 to the signal line and to perform the digital conversion on the pixel signal and output the pixel signal from the imaging element 5.

In the second imaging control, the system control unit 11 controls the imaging element 5 or a processing circuit provided on the same substrate as the imaging element 5 to perform addition control of adding pixel signals generated by two or more pixels 61 together. The control of adding the pixel signals generated by two or more pixels 61 together includes adding the pixel signals read out from each of the two or more pixels 61 to the signal line together in a state of an analog signal or a digital signal, or adding the charges accumulated in the photoelectric conversion units PD of the two or more pixels 61 together by the readout circuit, and then reading out the charges to the signal line as one pixel signal.

For example, the system control unit 11 causes the signal lines to individually read out pixel signals from n (n is a natural number of 2 or more) pixels 61 of the signal to be added together, and causes the processing circuit to derive an arithmetic mean of the n pixel signals (digital values). The processing of deriving the arithmetic mean may be performed by the system control unit 11 or the digital signal processing unit 17.

Alternatively, the system control unit 11 adds the charges accumulated in the photoelectric conversion units PD of the n pixels 61 together, reads out the pixel signal corresponding to the added charges to the signal line by the readout circuit, and outputs a value obtained by dividing the value after the digital conversion of the pixel signal read out to the signal line by n from the processing circuit. The processing of dividing by n may be performed by the system control unit 11 or the digital signal processing unit 17.

Alternatively, the system control unit 11 reads out the pixel signals from the n pixels 61 individually to the signal lines, adds the n pixel signals in the signal processing circuit 64 together in a state of analog signals, and outputs a value obtained by dividing the value after the digital conversion of the pixel signal after addition by n from the processing circuit.

In a case where the pixel signals of two or more pixels 61 are added together, it is preferable to add the pixel signals together after the digital conversion. Since there may be a variation in the maximum value of the pixel signal (analog value) read out from the pixel 61, the pixel signals subjected to the digital conversion are added together to eliminate the influence of the variation, and thus the pixel output can be obtained with high accuracy.

FIG. 12 is a schematic diagram showing a combination of pixels to be added together in the second imaging control. The system control unit 11 performs addition control of adding the pixel signals together with a plurality of pixels 61 that correspond to the same wavelength range and are closest to each other to be added together for the pixels 61 other than the low-sensitivity pixel 61GL.

In the example of FIG. 12, the system control unit 11 performs addition control of adding pixel signals (second signals) generated by the pixel 61R and the pixel 61R (pairs connected by a straight line with black circles at both ends in the drawing) closest to the pixel 61R together on one side in the row direction X. In addition, the system control unit 11 performs addition control of adding pixel signals (second signals) generated by the high-sensitivity pixel 61GH and the high-sensitivity pixel 61GH (pairs connected by a straight line with black circles at both ends in the drawing) closest to the high-sensitivity pixel 61GH together on the one side in the row direction X. In addition, the system control unit 11 performs addition control of adding pixel signals (second signals) generated by the pixel 61B and the pixel 61B (pairs connected by a straight line with black circles at both ends in the drawing) closest to the pixel 61B together on the one side in the row direction X.

In addition, the system control unit 11 performs first addition control of adding pixel signals (first signals) generated by the low-sensitivity pixel 61GLa and the low-sensitivity pixel 61GLb (pairs connected by a straight line with black circles at both ends in the drawing) closest to the low-sensitivity pixel 61GLa together on the one side in the row direction X. In addition, the system control unit 11 performs first addition control of adding pixel signals (first signals) generated by the low-sensitivity pixel 61GLb and the low-sensitivity pixel 61GLa (pairs connected by a straight line with black circles at both ends in the drawing) closest to the low-sensitivity pixel 61GLb together on the one side in the row direction X.

According to the addition example shown in FIG. 12, it is possible to obtain an image signal in which the size in the row direction X is reduced. In addition, in a case where two or more pixel signals are added together in a state of the analog signal, the time required for the digital conversion can be shortened. In addition, in both a case where two or more pixel signals are added together in a state of the analog signal and a case where two or more pixel signals are added together in a state of the digital signal, since the amount of data output from the substrate on which the imaging element 5 is mounted to the substrate on which the system control unit 11 is mounted can be reduced, image generation can be performed at high speed.

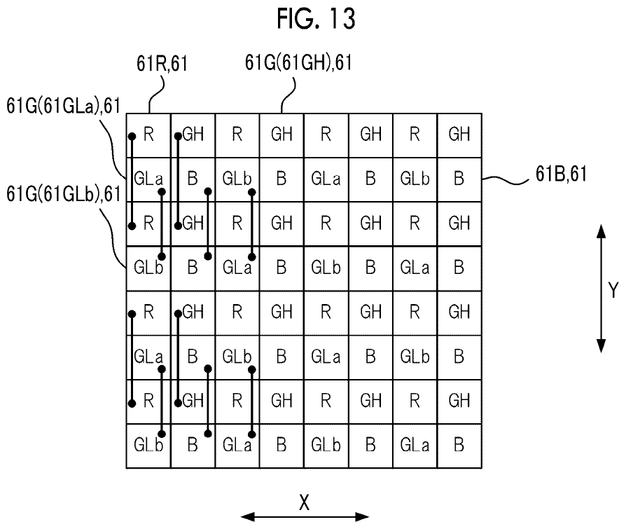

FIG. 13 is a schematic diagram showing another example of a combination of pixels to be added together in the second imaging control. In the example of FIG. 13, the system control unit 11 performs addition control of adding pixel signals (second signals) generated by the pixel 61R and the pixel 61R (pairs connected by a straight line with black circles at both ends in the drawing) closest to the pixel 61R together on one side in the column direction Y. In addition, the system control unit 11 performs addition control of adding pixel signals (second signals) generated by the high-sensitivity pixel 61GH and the high-sensitivity pixel 61GH (pairs connected by a straight line with black circles at both ends in the drawing) closest to the high-sensitivity pixel 61GH together on the one side in the column direction Y. In addition, the system control unit 11 performs addition control of adding pixel signals (second signals) generated by the pixel 61B and the pixel 61B (pairs connected by a straight line with black circles at both ends in the drawing) closest to the pixel 61B together on the one side in the column direction Y.

In addition, the system control unit 11 performs second addition control of adding pixel signals (first signals) generated by the low-sensitivity pixel 61GLa and the low-sensitivity pixel 61GLb (pairs connected by a straight line with black circles at both ends in the drawing) closest to the low-sensitivity pixel 61GLa together on the one side in the column direction Y. In addition, the system control unit 11 performs second addition control of adding pixel signals (first signals) generated by the low-sensitivity pixel 61GLb and the low-sensitivity pixel 61GLa (pairs connected by a straight line with black circles at both ends in the drawing) closest to the low-sensitivity pixel 61GLb together on the one side in the column direction Y.

According to the addition example shown in FIG. 13, it is possible to obtain an image in which the size in the column direction Y is reduced. In addition, by adding the pixel signals together, image generation can be performed at high speed as in the example of FIG. 12.

In the imaging element 5, since the low-sensitivity pixel group is disposed as shown in FIG. 3, both the addition of the pixel signals in the row direction X and the addition of the pixel signals in the column direction Y can be performed as shown in FIGS. 12 and 13, and various images according to the intention of the user can be generated. In a case where the addition control shown in FIG. 12 or FIG. 13 is performed, for example, the arithmetic mean of the pixel signals of the two high-sensitivity pixels 61GH is obtained, the arithmetic mean of the pixel signals of the two low-sensitivity pixels 61GL is obtained, and these two values are further averaged, so that the dynamic range can be expanded.

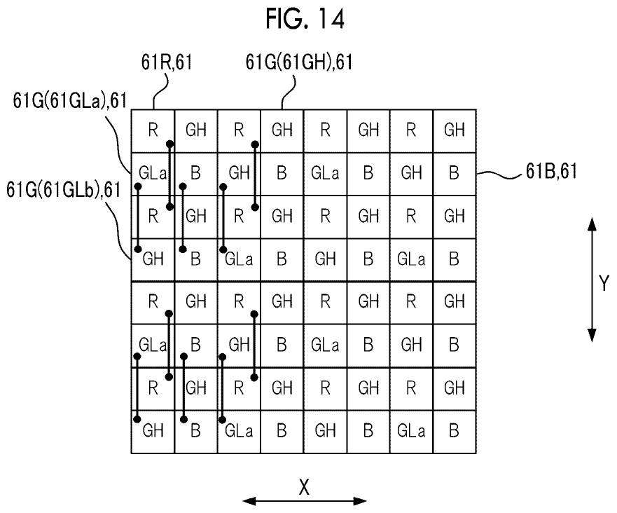

In the second imaging control, the system control unit 11 may perform control of adding the pixel signal generated by the low-sensitivity pixel 61GL and the pixel signal generated by the high-sensitivity pixel 61GH together for the pixel 61G. FIG. 14 shows a disposition example of the pixels 61 that is preferable in a case where such control is performed.

In the pixel disposition shown in FIG. 14, the low-sensitivity pixel 61GLb in the pixel row including the pixel 61G and the pixel 61B in FIG. 3 is replaced with the high-sensitivity pixel 61GH. The imaging element 5 having the pixel disposition shown in FIG. 14 is provided with a G pixel group in which the pixels 61G are two-dimensionally arranged in the row direction X and the column direction Y. In the G pixel group, in a case where one of the low-sensitivity pixels 61GL is set as a pixel of interest, a pixel 61G closest to the pixel of interest in the row direction X is set as the high-sensitivity pixel 61GH, and a pixel 61G closest to the pixel of interest in the column direction Y is set as the high-sensitivity pixel 61GH.

In the example of FIG. 14, the system control unit 11 performs addition control of adding pixel signals generated by the pixel 61R and the pixel 61R (pairs connected by a straight line with black circles at both ends in the drawing) closest to the pixel 61R together on the one side in the column direction Y. In addition, the system control unit 11 performs addition control of adding pixel signals generated by the pixel 61B and the pixel 61B (pairs connected by a straight line with black circles at both ends in the drawing) closest to the pixel 61B together on the one side in the column direction Y.

In addition, the system control unit 11 performs addition control of adding pixel signals generated by the low-sensitivity pixel 61GLa and the high-sensitivity pixel 61GH (pairs connected by a straight line with black circles at both ends in the drawing) closest to the low-sensitivity pixel 61GLa together on the one side in the column direction Y. In addition, the system control unit 11 performs addition control of adding pixel signals generated by the low-sensitivity pixel 61GLa and the high-sensitivity pixel 61GH (pairs connected by a straight line with black circles at both ends in the drawing) closest to the low-sensitivity pixel 61GLa together on the other side in the column direction Y.

According to the addition example shown in FIG. 14, it is possible to obtain an image in which the size in the column direction Y is reduced. In addition, by adding the pixel signals together, image generation can be performed at high speed as in the example of FIG. 12. In addition, since the pixel signals of the low-sensitivity pixel 61GLa and the high-sensitivity pixel 61GH are added together, the dynamic range can be expanded.

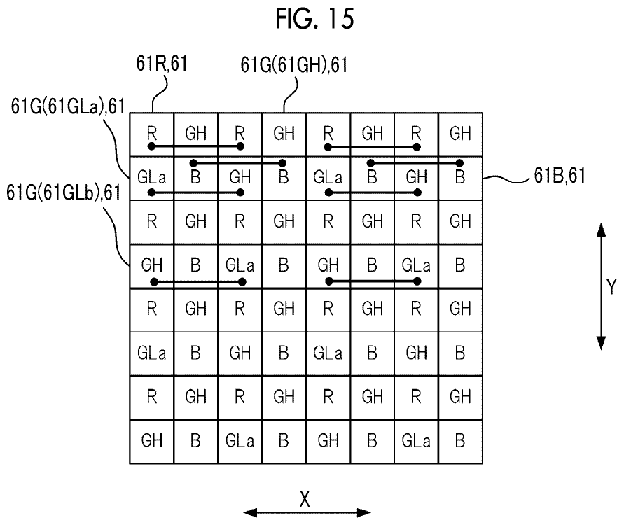

According to the pixel disposition shown in FIG. 14, addition as shown in FIG. 15 can also be performed. In the example of FIG. 15, the system control unit 11 performs addition control of adding pixel signals generated by the pixel 61R and the pixel 61R (pairs connected by a straight line with black circles at both ends in the drawing) closest to the pixel 61R together on the one side in the row direction X. In addition, the system control unit 11 performs addition control of adding pixel signals generated by the pixel 61B and the pixel 61B (pairs connected by a straight line with black circles at both ends in the drawing) closest to the pixel 61B together on the one side in the row direction X.

In addition, the system control unit 11 performs addition control of adding pixel signals generated by the low-sensitivity pixel 61GLa and the high-sensitivity pixel 61GH (pairs connected by a straight line with black circles at both ends in the drawing) closest to the low-sensitivity pixel 61GLa together on the one side in the row direction X. In addition, the system control unit 11 performs addition control of adding pixel signals generated by the low-sensitivity pixel 61GLa and the high-sensitivity pixel 61GH (pairs connected by a straight line with black circles at both ends in the drawing) closest to the low-sensitivity pixel 61GLa together on the other side in the row direction X.

According to the addition example shown in FIG. 15, it is possible to obtain an image in which the size in the row direction X is reduced. In addition, by adding the pixel signals together, image generation can be performed at high speed as in the example of FIG. 12. In addition, since the pixel signals of the low-sensitivity pixel 61GLa and the high-sensitivity pixel 61GH are added together, the dynamic range can be expanded. As described above, according to the pixel disposition shown in FIGS. 14 and 15, even in a case where any one of the pixel addition in the row direction X or the pixel addition in the column direction Y is performed, the pixel signals of the high-sensitivity pixel 61GH and the low-sensitivity pixel 61GL can be added together, and various images according to the intention of the user can be generated.

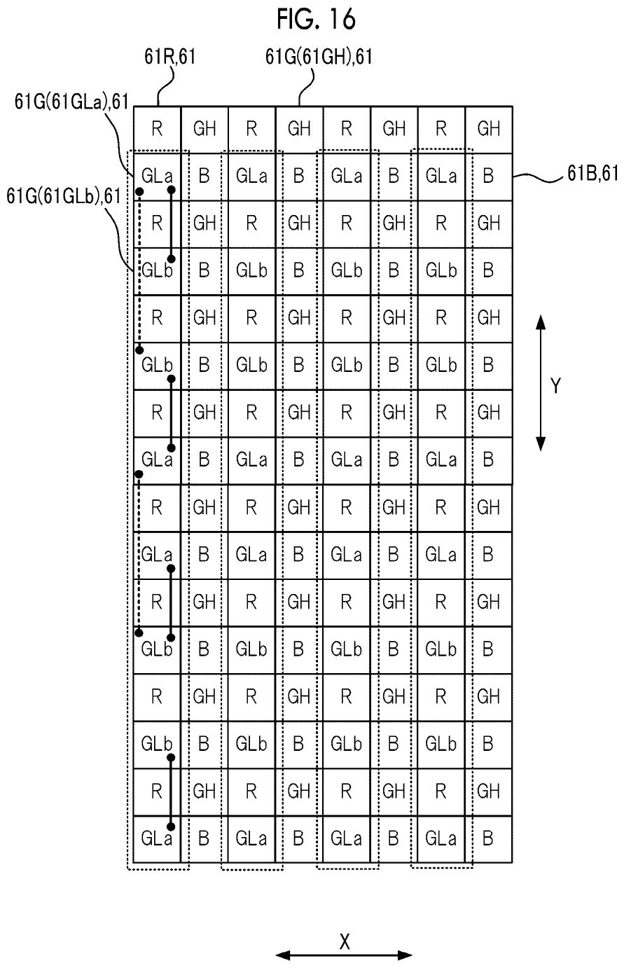

FIG. 16 is a diagram showing another modification example of the pixel disposition of the imaging element 5. In the pixel disposition shown in FIG. 16, the position of the pixel 61G is the same as that in FIG. 3, but the low-sensitivity pixel 61GLa and the low-sensitivity pixel 61GLb are disposed to have the following relationship. Among the pixels 61G on the imaging surface 60, a pixel group (pixels 61G in a range surrounded by a broken line frame in the drawing) including a plurality of low-sensitivity pixels 61GL arranged in the column direction Y is focused on. In the pixel group, in a case where one of the low-sensitivity pixels 61GL is set as a pixel of interest, two of the low-sensitivity pixels 61GL on both sides closest to the pixel of interest include one low-sensitivity pixel 61GL of the same type as the pixel of interest and the other low-sensitivity pixel 61GL of a different type from the pixel of interest.

In the pixel disposition shown in FIG. 16, the system control unit 11 performs third addition control of adding a signal generated by the pixel of interest and a signal generated by the low-sensitivity pixel 61GL second closest to the pixel of interest together on one side (one side in the column direction Y) of the pixel of interest, in each pixel group. In the third addition control, pixel signals of two low-sensitivity pixels 61GL of different types connected by a broken straight line shown in FIG. 16 are added together.

Further, the system control unit 11 performs fourth addition control of adding a signal generated by the pixel of interest and a signal generated by the low-sensitivity pixel 61GL closest to the pixel of interest together on one side (one side in the column direction Y) of the pixel of interest, in each pixel group. In the fourth addition control, pixel signals of two low-sensitivity pixels 61GL of different types connected by a solid straight line shown in FIG. 16 are added together.

As described above, according to the pixel disposition shown in FIG. 16, even in a case where pixel addition is performed in the same direction, two low-sensitivity pixels 61GL to be added together can be combined in a different manner. Therefore, it is possible to implement a large number of addition patterns and to perform flexible addition control according to the required image quality, as compared with the pixel disposition in FIG. 3.

In the above description, the imaging element 5 can perform color imaging, but the present invention is not limited thereto. The imaging element 5 may also have a configuration in which the color filter CF is omitted. In addition, in the addition example shown in FIG. 12, the pixel signals of the two pixels 61 are added together, but control of adding the pixel signals of four or more pixels 61 together may be performed. For example, in FIG. 12, control of adding pixel signals generated by four low-sensitivity pixels 61GL in the same pixel row together, adding pixel signals generated by four pixels 61R in the same pixel row together, adding pixel signals generated by four pixels 61B in the same pixel row together, and adding pixel signals generated by four high-sensitivity pixels 61GH in the same pixel row together may be performed.

In addition, although it is assumed that the imaging element 5 is provided with two types of low-sensitivity pixels 61GL having different phases of the plurality of openings 71, three or more types of low-sensitivity pixels 61GL may be provided in the imaging element 5. In this case, in a case where the control of adding the pixel signals generated by the three pixels 61 together is performed, it is preferable that the control of adding the pixel signals generated by the three types of low-sensitivity pixels 61GL together is performed for the low-sensitivity pixels 61GL.

Next, a configuration of a smartphone which is another embodiment of the imaging apparatus according to the present invention will be described.

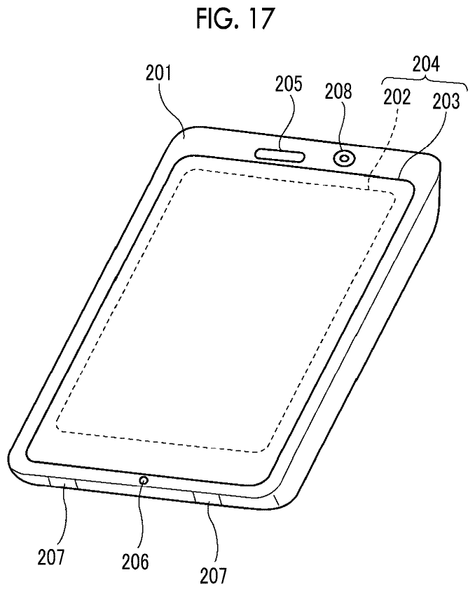

FIG. 17 is a diagram showing an exterior of the smartphone 200. The smartphone 200 shown in FIG. 17 includes a housing 201 having a flat plate shape and comprises a display and input unit 204 in which a display panel 202 as a display unit and an operation panel 203 as an input unit are integrated on one surface of the housing 201.

In addition, the housing 201 comprises a speaker 205, a microphone 206, an operation unit 207, and a camera unit 208. The configuration of the housing 201 is not limited thereto and, for example, a configuration in which the display unit and the input unit are independently disposed can be employed, or a configuration having a folded structure or a sliding mechanism can be employed.

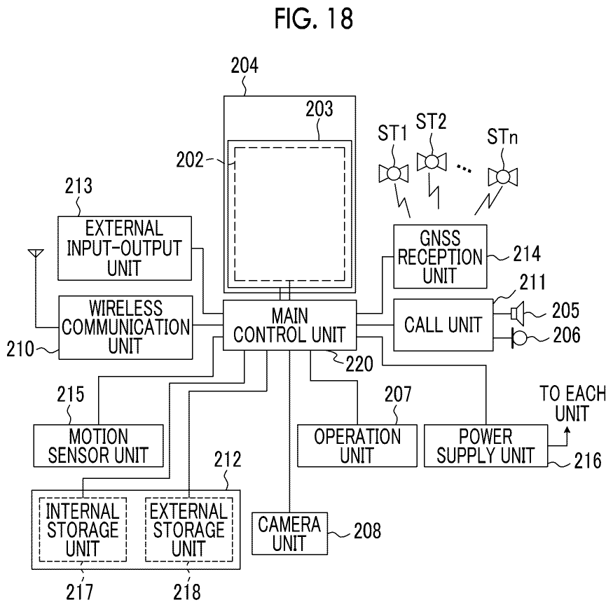

FIG. 18 is a block diagram showing a configuration of the smartphone 200 shown in FIG. 17.

As shown in FIG. 18, the smartphone comprises, as main constituents, a wireless communication unit 210, the display and input unit 204, a call unit 211, the operation unit 207, the camera unit 208, a storage unit 212, an external input-output unit 213, a global navigation satellite system (GNSS) reception unit 214, a motion sensor unit 215, a power supply unit 216, and a main control unit 220.

In addition, the smartphone 200 comprises, as a main function, a wireless communication function of performing mobile wireless communication via a base station apparatus BS (not shown) and a mobile communication network NW (not shown).

The wireless communication unit 210 performs wireless communication with the base station apparatus BS accommodated in the mobile communication network NW in accordance with instructions from the main control unit 220. By using the wireless communication, transmission and reception of various file data such as audio data and image data, electronic mail data, or the like and reception of web data, streaming data, or the like are performed.

The display and input unit 204 is a so-called touch panel that visually delivers information to the user by displaying images (still images and video images), text information, or the like and that detects a user operation with respect to the displayed information under control of the main control unit 220. The display and input unit 204 comprises the display panel 202 and the operation panel 203.

The display panel 202 uses a liquid crystal display (LCD), an organic electroluminescence display (OELD), or the like as a display device.

The operation panel 203 is a device that is placed such that an image displayed on a display surface of the display panel 202 can be visually recognized, and that detects one or a plurality of coordinates operated with a finger of the user or with a stylus. In a case where the device is operated with the finger of the user or with the stylus, a detection signal generated by the operation is output to the main control unit 220. Next, the main control unit 220 detects an operation position (coordinates) on the display panel 202 based on the received detection signal.

As shown in FIG. 18, although the display panel 202 and the operation panel 203 of the smartphone 200 shown as an embodiment of the imaging apparatus according to the present invention are integrated to constitute the display and input unit 204, the operation panel 203 is disposed to completely cover the display panel 202.

In a case where such disposition is employed, the operation panel 203 may comprise a function of detecting the user operation even in a region outside the display panel 202. In other words, the operation panel 203 may comprise a detection region (hereinafter, referred to as a display region) for an overlapping portion overlapping with the display panel 202 and a detection region (hereinafter, referred to as a non-display region) for an outer edge portion, other than the overlapping portion, that does not overlap with the display panel 202.

A size of the display region and a size of the display panel 202 may completely match, but both sizes do not need to match. In addition, the operation panel 203 may comprise two sensitive regions of the outer edge portion and an inner portion other than the outer edge portion. Furthermore, a width of the outer edge portion is appropriately designed depending on a size and the like of the housing 201.

Furthermore, examples of a position detection method employed in the operation panel 203 include a matrix switch method, a resistive membrane system, a surface acoustic wave method, an infrared method, an electromagnetic induction method, and a capacitance method, and any method can be employed.

The call unit 211 comprises the speaker 205 or the microphone 206, and converts voice of the user input through the microphone 206 into audio data processable in the main control unit 220 and outputs the audio data to the main control unit 220, or decodes audio data received by the wireless communication unit 210 or by the external input-output unit 213 and outputs the decoded audio data from the speaker 205.

In addition, as shown in FIG. 17, for example, the speaker 205 can be mounted on the same surface as a surface on which the display and input unit 204 is provided, and the microphone 206 can be mounted on a side surface of the housing 201.

The operation unit 207 is a hardware key that uses a key switch or the like, and receives instructions from the user. For example, as shown in FIG. 17, the operation unit 207 is a push button-type switch that is mounted on the side surface of the housing 201 of the smartphone 200, and is turned on by being pressed with the finger or the like and is set to an OFF state by a restoring force of a spring or the like in a case where the finger is released.

The storage unit 212 stores a control program and control data of the main control unit 220, application software, address data in which a name, a telephone number, or the like of a communication counterpart is associated, transmitted and received electronic mail data, web data downloaded by web browsing, and downloaded contents data, and temporarily stores streaming data or the like. In addition, the storage unit 212 is configured with an internal storage unit 217 incorporated in the smartphone and with an external storage unit 218 that has a slot for an attachable and detachable external memory.

Each of the internal storage unit 217 and the external storage unit 218 constituting the storage unit 212 is implemented using a storage medium such as a memory (for example, a MicroSD (registered trademark) memory) of a flash memory type, a hard disk type, a multimedia card micro type, or a card type, a random access memory (RAM), or a read only memory (ROM).

The external input-output unit 213 serves as an interface with all external apparatuses connected to the smartphone 200 and is directly or indirectly connected to other external apparatuses by communication or the like (for example, a universal serial bus (USB), IEEE1394, Bluetooth (registered trademark), radio frequency identification (RFID), infrared communication (Infrared Data Association (IrDA) (registered trademark)), Ultra Wideband (UWB) (registered trademark), or ZigBee (registered trademark)) or through a network (for example, Ethernet (registered trademark) or a wireless local area network (LAN)).

For example, the external apparatuses connected to the smartphone 200 include a wired/wireless headset, a wired/wireless external charger, a wired/wireless data port, a memory card and a subscriber identity module (SIM)/user identity module (UIM) card connected via a card socket, an external audio and video apparatus connected via an audio and video input/output (I/O) terminal, an external audio and video apparatus connected in a wireless manner, a smartphone connected in a wired/wireless manner, a personal computer connected in a wired/wireless manner, and an earphone.

The external input-output unit 213 can deliver data transferred from the external apparatuses to each constituent in the smartphone 200 or transfer data in the smartphone 200 to the external apparatuses.

The GNSS reception unit 214 receives GNSS signals transmitted from GNSS satellites ST1 to STn, executes positioning computation processing based on the received plurality of GNSS signals, and detects a position consisting of a latitude, a longitude, and an altitude of the smartphone 200 in accordance with instructions from the main control unit 220. In a case where positional information can be acquired from the wireless communication unit 210 or from the external input-output unit 213 (for example, a wireless LAN), the GNSS reception unit 214 can detect the position using the positional information.

The motion sensor unit 215 comprises, for example, a three-axis acceleration sensor and detects a physical motion of the smartphone 200 in accordance with instructions from the main control unit 220. By detecting the physical motion of the smartphone 200, a movement direction or acceleration of the smartphone 200 is detected. The detection result is output to the main control unit 220.

The power supply unit 216 supplies power stored in a battery (not shown) to each unit of the smartphone 200 in accordance with instructions from the main control unit 220.

The main control unit 220 comprises a microprocessor, operates in accordance with the control program and with the control data stored in the storage unit 212, and manages and controls each unit of the smartphone 200. The microprocessor of the main control unit 220 has the same function as the system control unit 11. In addition, the main control unit 220 comprises a mobile communication control function of controlling each unit of a communication system and an application processing function in order to perform voice communication or data communication through the wireless communication unit 210.

The application processing function is implemented by operating the main control unit 220 in accordance with the application software stored in the storage unit 212. For example, the application processing function is an infrared communication function of performing data communication with counter equipment by controlling the external input-output unit 213, an electronic mail function of transmitting and receiving electronic mails, or a web browsing function of viewing a web page.

In addition, the main control unit 220 comprises an image processing function such as displaying an image on the display and input unit 204 based on image data (data of a still image or of a video image) such as reception data or downloaded streaming data.

The image processing function refers to a function of causing the main control unit 220 to decode the image data, perform image processing on the decoding result, and display the image on the display and input unit 204.

Furthermore, the main control unit 220 executes a display control of the display panel 202 and an operation detection control of detecting user operations performed through the operation unit 207 and through the operation panel 203.

By executing the display control, the main control unit 220 displays an icon for starting the application software or a software key such as a scroll bar or displays a window for creating an electronic mail.

The scroll bar refers to a software key for receiving an instruction to move a display portion of an image, such as a large image that does not fit in the display region of the display panel 202.

In addition, by executing the operation detection control, the main control unit 220 detects the user operation performed through the operation unit 207, receives an operation with respect to the icon and an input of a text string in an input field of the window through the operation panel 203, or receives a request for scrolling the display image made through the scroll bar.

Furthermore, by executing the operation detection control, the main control unit 220 comprises a touch panel control function of determining whether the operation position on the operation panel 203 is in the overlapping portion (display region) overlapping with the display panel 202 or is in the outer edge portion (non-display region), other than the overlapping portion, not overlapping with the display panel 202 and of controlling the sensitive region of the operation panel 203 or a display position of the software key.

In addition, the main control unit 220 can detect a gesture operation with respect to the operation panel 203 and execute a function set in advance in accordance with the detected gesture operation.

The gesture operation is not a simple touch operation in the related art and means an operation of drawing a path with the finger or the like, designating a plurality of positions at the same time, or as a combination thereof, drawing a path from at least one of the plurality of positions.

The camera unit 208 includes the lens device 40, the imaging element 5, and the digital signal processing unit 17 shown in FIG. 1.

Captured image data generated by the camera unit 208 can be stored in the storage unit 212 or output through the external input-output unit 213 or through the wireless communication unit 210.

In the smartphone 200 shown in FIG. 18, the camera unit 208 is mounted on the same surface as the display and input unit 204. However, a mount position of the camera unit 208 is not limited thereto. The camera unit 208 may be mounted on a rear surface of the display and input unit 204.

In addition, the camera unit 208 can be used for various functions of the smartphone 200. For example, an image acquired by the camera unit 208 can be displayed on the display panel 202, or the image of the camera unit 208 can be used as one of operation inputs of the operation panel 203.

In addition, in a case where the GNSS reception unit 214 detects the position, the position can be detected by referring to the image from the camera unit 208. Furthermore, by referring to the image from the camera unit 208, it is possible to determine an optical axis direction of the camera unit 208 of the smartphone 200 or to determine the current use environment without using the three-axis acceleration sensor or by using the three-axis acceleration sensor in combination. Of course, the image from the camera unit 208 can also be used in the application software.

In addition, image data of a still image or of a video image to which the positional information acquired by the GNSS reception unit 214, voice information (may be text information acquired by performing voice to text conversion via the main control unit or the like) acquired by the microphone 206, posture information acquired by the motion sensor unit 215, or the like is added can be stored in the storage unit 212 or be output through the external input-output unit 213 or through the wireless communication unit 210.

Although various embodiments have been described above, it goes without saying that the present invention is not limited to these examples. It is apparent that those skilled in the art may perceive various modification examples or correction examples within the scope disclosed in the claims, and those examples are also understood as falling within the technical scope of the present invention. In addition, each of constituents in the embodiments may be combined in any manner without departing from the gist of the invention.

The present application is based on Japanese Patent Application (JP2023-013457) filed on Jan. 31, 2023, the content of which is incorporated in the present application by reference.

### EXPLANATION OF REFERENCES

1: imaging lens
2: stop
4: lens control unit
5: imaging element
8: lens drive unit
9: stop drive unit
11: system control unit
14, 207: operation unit
15: memory control unit
16: memory
17: digital signal processing unit
20: external memory control unit
21: storage medium
22a: display controller
22b: display surface
22: display device
24: control bus
25: data bus
40: lens device
60: imaging surface
61, 61R, 61G, 61B: pixel
61GL, 61GLa, 61GLb: low-sensitivity pixel
61GH: high-sensitivity pixel
62: pixel row
63: drive circuit
64: signal processing circuit
A1, A2: range
gh, gl, gav: graph
PD: photoelectric conversion unit
CF: color filter
ML: microlens
70a, 70b: light reducing member
71: opening
L: ray
C1, C2a, C2b, C3: curve
100A: body part
100: digital camera
200: smartphone
201: housing
202: display panel
203: operation panel
204: display and input unit
205: speaker
206: microphone
208: camera unit
210: wireless communication unit
211: call unit
212: storage unit
213: external input-output unit
214: GNSS reception unit
215: motion sensor unit
216: power supply unit
217: internal storage unit
218: external storage unit
220: main control unit

What is claimed is:

1. An imaging apparatus comprising:
an imaging element that includes a plurality of pixels; and
a processor,
wherein the plurality of pixels include first pixels in each of which a light reducing member having a plurality of openings is disposed and second pixels in each of which the light reducing member is not provided,
the processor is configured to:
perform addition control of adding signals generated by two or more of the plurality of pixels together, and
in the addition control, control of adding first signals generated by the first pixels together and adding second signals generated by the second pixels together is performed.

2. The imaging apparatus according to claim 1,
wherein the first pixels include a plurality of types in which dispositions of the plurality of openings are different from each other, and
two or more of the first signals added together in the addition control include signals generated by the first pixels of different types.

3. The imaging apparatus according to claim 2,
wherein the plurality of types of the first pixels have different phases of the plurality of openings.

4. The imaging apparatus according to claim 2,
wherein the imaging element has a pixel group including a plurality of the first pixels which are two-dimensionally arranged, and
in the pixel group, one of the first pixels is set as a pixel of interest, and the first pixel of a type different from the pixel of interest is disposed as the first pixel closest to the pixel of interest in a first direction of the pixel of interest and is disposed as the first pixel closest to the pixel of interest in a second direction intersecting the first direction of the pixel of interest.

5. The imaging apparatus according to claim 4,
wherein the processor is configured to:
perform first addition control of adding a first signal generated by the pixel of interest and a first signal generated by the first pixel closest to the pixel of interest in the first direction of the pixel of interest together, and second addition control of adding the first signal generated by the pixel of interest and a first signal generated by the first pixel closest to the pixel of interest in the second direction of the pixel of interest together.

6. The imaging apparatus according to claim 2,
wherein the imaging element has a pixel group including a plurality of the first pixels arranged in one direction, and
in the pixel group, one of the first pixels is set as a pixel of interest, and one of the first pixels on both sides closest to the pixel of interest is the first pixel of a same type as the pixel of interest and other of the first pixels on the both sides is the first pixel of a different type from the pixel of interest.

7. The imaging apparatus according to claim 6,
wherein the processor is configured to:
perform, on one side of the pixel of interest in the one direction, third addition control of adding a first signal generated by the pixel of interest and a first signal generated by the first pixel second closest to the pixel of interest together, and fourth addition control of adding the first signal generated by the pixel of interest and a first signal generated by the first pixel closest to the pixel of interest together.

8. The imaging apparatus according to claim 1,
wherein the processor is configured to:
add digitally converted signals together in the addition control.

9. The imaging apparatus according to claim 2,
wherein the processor is configured to:
add digitally converted signals together in the addition control.

10. The imaging apparatus according to claim 3,
wherein the processor is configured to:
add digitally converted signals together in the addition control.

11. An imaging apparatus comprising:
an imaging element that includes a plurality of pixels; and
a processor,
wherein the plurality of pixels include a first pixel in which a light reducing member having a plurality of openings is disposed and a second pixel in which the light reducing member is not provided,
the processor is configured to:
perform addition control of adding signals generated by two or more of the plurality of pixels together, and
in the addition control, control of adding a first signal generated by the first pixel and a second signal generated by the second pixel together is performed.

12. The imaging apparatus according to claim 11,
wherein the processor is configured to:
perform control of adding the first signal which has been digitally converted and the second signal which has been digitally converted together.

13. A control method of controlling an imaging element that includes a plurality of pixels,
wherein the plurality of pixels include first pixels in each of which a light reducing member having a plurality of openings is disposed and second pixels in each of which the light reducing member is not provided,
the method comprising:
performing addition control of adding signals generated by two or more of the plurality of pixels together, and
in the addition control, control of adding first signals generated by the first pixels together and adding second signals generated by the second pixels together is performed.

14. A non-transitory computer readable medium storing a control program of controlling an imaging element that includes a plurality of pixels,
wherein the plurality of pixels include first pixels in each of which a light reducing member having a plurality of openings is disposed and second pixels in each of which the light reducing member is not provided,
the program causing a processor to execute:
performing addition control of adding signals generated by two or more of the plurality of pixels together, and
in the addition control, control of adding first signals generated by the first pixels together and adding second signals generated by the second pixels together is performed.

15. An imaging element comprising:
a plurality of pixels,
wherein the plurality of pixels include first pixels in each of which a light reducing member having a plurality of openings is disposed and second pixels in each of which the light reducing member is not provided, and
in a case where an instruction to add signals generated by two or more of the plurality of pixels together and to output the added signals is received, the imaging element adds first signals generated by the first pixels together, adds second signals generated by the second pixels together, and outputs the added signals.
